(19) United States
(12) Patent Application Publication
(10) Pub. No.: US 2025/0385122 A1
(43) Pub. Date: Dec. 18, 2025

(54) TEXTURED SUSCEPTOR FOR IMPROVED THERMAL UNIFORMITY

(71) Applicant: Applied Materials, Inc., Santa Clara, CA (US)

(72) Inventors: YEN LIN LEOW, San Jose, CA (US); HYEON GEU KIM, Santa Clara, CA (US); GAGANDEEP SINGH JOSHI, Fresno, CA (US)

(21) Appl. No.: 19/227,313

(22) Filed: Jun. 3, 2025

Related U.S. Application Data
(60) Provisional application No. 63/659,251, filed on Jun. 12, 2024.

(51) Int. Cl. H01L 21/687; C30B 25/12; H01L 21/67

(52) U.S. Cl. CPC H01L 21/68735; C30B 25/12; H01L 21/67098; H01L 21/68757; H01L 21/68785

(57) ABSTRACT

Embodiments described herein relate to an apparatus that includes a substrate with a first emissivity, where the substrate includes a first surface, a second surface, and a sidewall surface that couples the first surface to the second surface. In an embodiment, a textured region is on the first surface, where the textured region includes a second emissivity that is higher than the first emissivity.

### CROSS-REFERENCE TO RELATED APPLICATIONS

This application claims the benefit of U.S. Provisional Application No. 63/659,251, filed on Jun. 12, 2024, the entire contents of which are hereby incorporated by reference herein.

### BACKGROUND

### 1) Field

Embodiments relate to the field of semiconductor manufacturing and, in particular, textured susceptors for improved thermal uniformity within epitaxy or rapid thermal processing tools.

### 2) Description of Related Art

Rapid thermal processing (RTP) and epitaxy reactors have chamber enclosures that are transparent to thermal radiation. Lamps outside of the chamber enclosure emit thermal radiation that passes through the chamber enclosure in order to rapidly heat a susceptor that is used to hold the substrate (e.g., a wafer or the like). The susceptor is made of a high emissivity material and/or includes a high emissivity coating in order to promote quick thermal heating and cooling. Such rapid heating and cooling processes may be referred to as temperature ramps.

The lamps can be arranged in concentric patterns or linear patterns. The arrangement of the lamps in conjunction with the design of a reflector around the lamps can be used to provide a more uniform heating of the susceptor. However, even with careful design, the variability in the emission pattern of the individual lamps and other non-uniformities can lead to some temperature deviations across the susceptor.

### SUMMARY

Embodiments described herein relate to an apparatus that includes a substrate with a first emissivity, where the substrate includes a first surface, a second surface, and a sidewall surface that couples the first surface to the second surface. In an embodiment, a textured region is on the first surface, where the textured region includes a second emissivity that is higher than the first emissivity.

Embodiments described herein relate to a tool that includes a chamber, and a susceptor in the chamber. In an embodiment, the susceptor includes a surface with a textured region. In an embodiment, a lamp is outside of the chamber, and the lamp is configured to emit thermal radiation that passes through the chamber and heats the susceptor.

Embodiments described herein relate to a method that includes heating a susceptor to a first temperature, where the susceptor has a textured region over at least a portion of a surface of the susceptor. In an embodiment, the method further includes bringing the susceptor to a second temperature that is higher than the first temperature in under two minutes, where the second temperature is at least 250° C. higher than the first temperature. In an embodiment, the method further includes bringing the susceptor to a third temperature that is lower than the second temperature in under two minutes, where the third temperature is at least 250° C. lower than the second temperature.

### BRIEF DESCRIPTION OF THE DRAWINGS

FIG. 1 is a tool for rapidly heating a substrate on a susceptor, in accordance with an embodiment.

FIG. 2A is a graph of the ramp rates during the heating of a susceptor with a first emissivity and a substrate with a second emissivity, in accordance with an embodiment.

FIG. 2B is a graph of the ramp rates during the cooling of a susceptor with a first emissivity and a substrate with a second emissivity, in accordance with an embodiment.

FIG. 3A is a plan view illustration of a susceptor with a textured region with a higher emissivity, in accordance with an embodiment.

FIG. 3B is a zoomed in plan view illustration of the textured region that shows a hexagonal honeycomb pattern, in accordance with an embodiment.

FIG. 3C is a cross-sectional illustration of the textured region showing the holes into the surface of the susceptor, in accordance with an embodiment.

FIG. 3D is a cross-sectional illustration of a susceptor with textured regions on the top surface and the bottom surface of the susceptor, in accordance with an embodiment.

FIG. 4 is a cross-sectional schematic illustrating the heat flux from a plurality of lamps and an underlying susceptor with textured regions that are arranged to line up with low flux regions from the lamps in order to provide more uniform heating, in accordance with an embodiment.

FIGS. 5A-5E are plan view illustrations of susceptors with texturized regions with various patterns, in accordance with an embodiment.

FIG. 6 is a plan view illustration of a susceptor surrounded by a process kit that is texturized to improve heating of gas flowing into the chamber, in accordance with an embodiment.

FIG. 7 is a flow diagram of a process for rapidly ramping up and ramping down a temperature of a susceptor, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include apparatuses with textured susceptors for improved thermal uniformity and methods of using such susceptors. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, rapid thermal processing (RTP) and epitaxy tools require high temperature uniformity at the susceptor in order to provide the desired uniformity in the process results. For epitaxy and other RTP processes, even small amounts of temperature non-uniformity can lead to process variability across the substrate, such as film thickness variations, dopant concentration variations, and/or the like. Despite the effort provided in the design of such tools, some amount of uneven heating is expected due to limitations in one or more of lamp design, reflector design, processing condition non-uniformities, and/or the like.

Accordingly, embodiments disclosed herein include a susceptor design that can accommodate such tool non-uniformities in order to provide greater control of susceptor temperature uniformity. Particularly, embodiments disclosed herein may include forming one or more textured regions across surfaces of the susceptor. The textured regions may be designed in order to provide a localized increase in the emissivity. By increasing the emissivity, the textured regions are able to heat up more quickly. Accordingly, regions that receive a lower heat flux from the lamps can be heated at approximately the same rate as regions that receive a higher heat flux from the lamps. That is, by positioning the textured regions at “cold” spots, the “cold” spots can be heated faster to provide a more consistent temperature across the susceptor, and the “cold” spots can be minimized and/or eliminated. The improved temperature uniformity may lead to improved process outcome uniformity, such as by improving the thickness uniformity of a film formed on a substrate supported by the susceptor.

In an embodiment, the textured regions maintain the same material composition as the remainder of the susceptor. However, the textured surface may reduce the reflection coefficient, which effectively increases the emissivity. In some embodiments, the textured regions may be precisely engineered and patterned using laser ablation processes. The patterned features may have dimensions (e.g., depths, widths, etc.) that are between approximately 100 nm and approximately 5.0 μm. The layout of the patterned features (e.g., holes, trenches, etc.) can include any suitable layout. For example, a honeycomb pattern may be used or a random pattern may be used.

In an embodiment, the textured regions may also be provided proximate to the gas inlet of the tool. As such, the gas can be heated rapidly as it enters the chamber. Such rapid heating may be useful for improving some processing operations. In such an embodiment, the textured regions may also be provided on a process kit that surrounds the susceptor.

Embodiments disclosed herein provide significant benefits compared to existing RTP and epitaxy tools. For example, the ability to tune susceptor temperature uniformity simplifies one or more of the reflector design, the lamp design and layout, or the gas injection scheme. Further, zone power control of the lamps may be reduced. That is, there may be a need for fewer zones for controlling the uniformity of the susceptor temperature. Embodiments disclosed herein also allow for local temperature modulation within the substrate and/or across the process kit. Texturizing the susceptor also enables venting of gasses between the substrate and the susceptor. For example, when the substrate is loaded/unloaded or when changes are made to the chamber pressure while a substrate is on the susceptor, the textured surfaces provides gas vent channels that prevent slippage of the substrate. Additionally, increasing the emissivity of the susceptor allows for faster temperature ramps (up and/or down) during processing recipes. This provides a reduction in the duration of a process recipe, which can lead to throughput gains. As such, cost of ownership of the tool will be decreased.

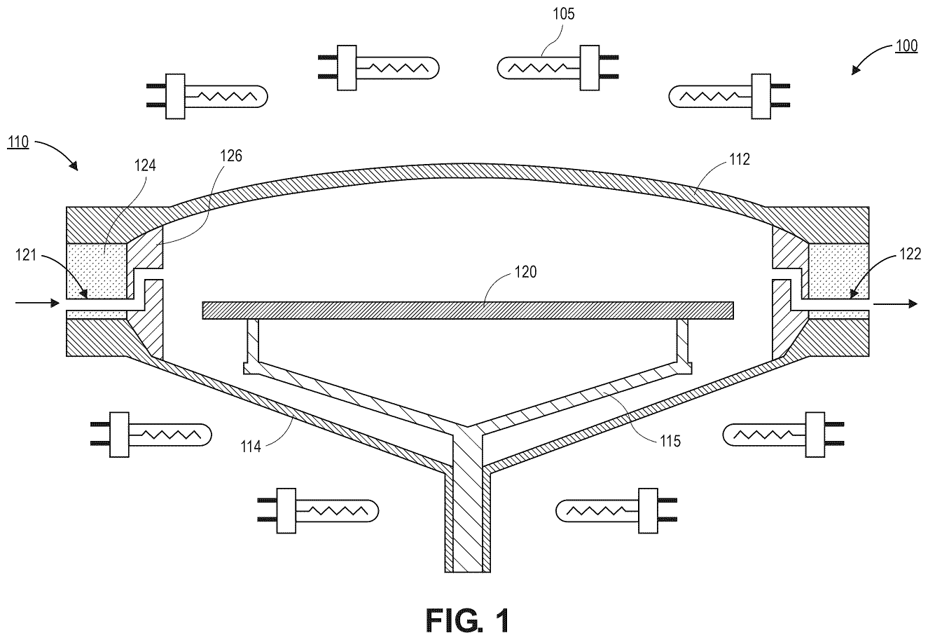

Referring now to FIG. 1, a cross-sectional illustration of a tool 100 is shown, in accordance with an embodiment. The tool 100 may include an RTP tool 100, an epitaxy tool 100, or the like. In an embodiment, the tool 100 may comprise a chamber 110. The chamber 110 may comprise an upper dome 112 and a lower dome 114. The upper dome 112 and the lower dome 114 may comprise materials that are substantially transparent to thermal radiation. For example, the upper dome 112 and the lower dome 114 may comprise quartz or the like. In some embodiments, the upper dome 112 and the lower dome 114 may be referred to as a wall of the chamber, a lid of the chamber, a bottom of the chamber, and/or the like. The upper dome 112 may be separated from the lower dome 114 by a ring 124. In some embodiments, one or more clamps (not shown) may compress the upper dome 112 and the lower dome 114 against the ring 124 in order to provide a seal to the chamber 110. A liner 126 may be provided along an interior surface of the ring 124.

In an embodiment, an inlet 121 may be provided along a first sidewall of the chamber 110, and an outlet 122 may be provided along a second sidewall of the chamber 110. The inlet 121 may pass through the ring 124 and the liner 126, and the outlet 122 may also pass through the ring 124 and the liner 126. As indicated by the arrows, gas may enter the chamber 110 through the inlet 121 and exit the chamber 110 through the outlet 122. The gas may flow across the interior of the chamber 110 over the susceptor 120.

In an embodiment, the susceptor 120 may be supported by a support 115. Lift pins and other features may also be provided inside the chamber 110, but are omitted from FIG. 1 for clarity. In an embodiment, the susceptor 120 may be any suitable substrate material that can be heated rapidly with thermal radiation. For example, the susceptor 120 may comprise silicon, silicon and carbon (e.g., SiC), graphite, or silicon carbide coated with graphite. In other embodiments, the susceptor 120 may comprise any material or materials with an emissivity of approximately 0.85 or higher. In embodiments described herein, the susceptor 120 may have one or more textured regions (not shown). A more detailed description of the textured regions will be provided in greater detail below. In embodiments described herein, the susceptor 120 may be more simply referred to as a substrate.

In an embodiment, one or more lamps 105 may be provided outside of the chamber 110. The lamps 105 may be provided in any suitable arrangement. For example, the lamps 105 may be in a linear arrangement or a concentric arrangement. The lamps 105 may emit thermal radiation that passes through the upper dome 112 and/or the lower dome 114. The thermal radiation is absorbed by the top and/or bottom surface of the susceptor 120 in order to rapidly heat the susceptor 120. In an embodiment, a reflector (not shown) may be provided around the lamps 105 in order to reflect thermal radiation emitted away from the chamber 110 back towards the susceptor 120 in order to increase the efficiency of the tool 100.

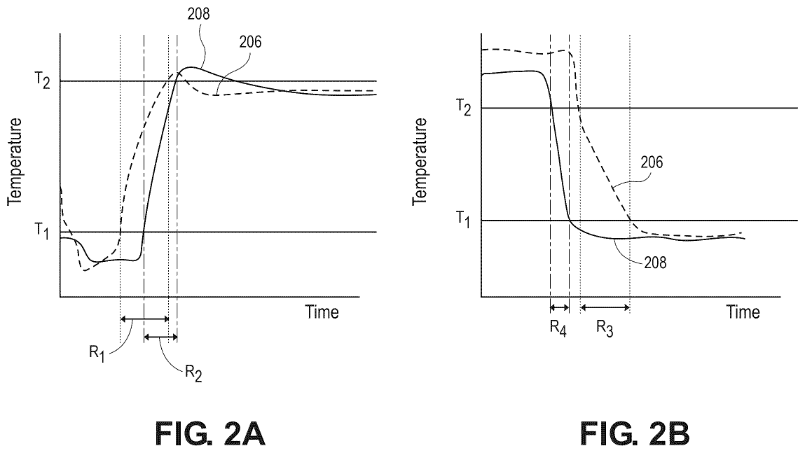

Processing recipes that are implemented in an RTP tool or an epitaxy tool similar to tool 100, may include one or more temperature ramps from a first (lower) temperature to a second (higher) temperature, or from the second (higher) temperature to the first (lower) temperature. For example, in a typical chamber cleaning recipe, a temperature ramp between approximately 600° C. and approximately 950° C. may be used. In order to improve throughput of the tool 100, the ramp rate of the temperature ramps should be as fast as possible. The rate at which the susceptor is heated is generally controlled by the Stefan-Boltzmann law. In accordance with the law, an increase in emissivity may result in an increase in the rate of temperature change. This trend is shown in the graphs in FIGS. 2A and 2B.

Referring now to FIG. 2A, a graph of temperature (Y-axis) versus time (X-axis) is shown for a first susceptor 206 with a first emissivity and a second susceptor 208 with a second emissivity. The first emissivity may be lower than the second emissivity. Aside from the emissivity, the first susceptor 206 and the second susceptor 208 may be substantially similar. For example, both the first susceptor 206 and the second susceptor 208 may comprises the same material, but the second susceptor 208 may comprise a textured surface in order to decrease the reflection coefficient. As shown, the first susceptor 206 has a first duration R₁ to increase from a first temperature T₁ to a second temperature T₂, while the second susceptor 208 has a shorter second duration R₂ to increase from the first temperature T₁ to the second temperature T₂. That is, the ramp rate for the second susceptor 208 with the higher emissivity is higher than the ramp rate for the first susceptor 206.

Similarly, FIG. 2B illustrates a graph showing the ramp rates for the first susceptor 206 and the second susceptor 208 from the second temperature T₂ to the first temperature T₁. As shown, the first susceptor 206 has a third duration R₃ for the ramp down, and the second susceptor 208 has a shorter fourth duration R₄ for the ramp down. Accordingly, the higher emissivity allows for the temperature ramps (both up and down) to occur faster. This enables a more efficient use of the tool 100 since the duration of the processing recipe can be reduced, and the cost of ownership of the tool 100 is decreased.

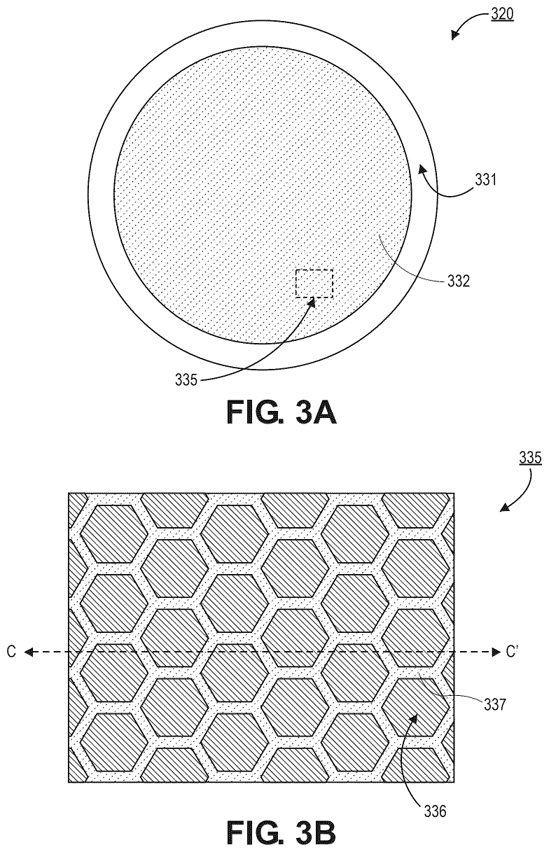

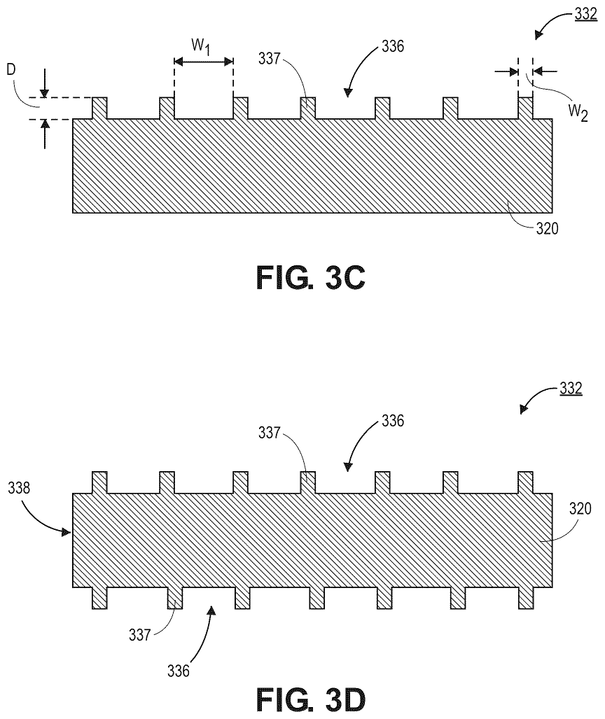

Referring now to FIG. 3A, a plan view illustration of a susceptor 320 is shown, in accordance with an embodiment. In an embodiment, the top surface 331 of the susceptor 320 is shown in FIG. 3A. The susceptor 320 may comprise a substrate with any suitable material, such as silicon, silicon carbide, graphite, or a silicon carbide substrate with a graphite coating. Additionally, the top surface 331 may include a textured region 332. The textured region 332 may include an engineered surface that is designed to reduce the reflection coefficient of the top surface 331. That is, the textured region 332 may comprise the same material composition as the portion of the top surface 331 that is not textured. Stated differently, the textured region 332 is not a coating that is applied over portions of the top surface 331. In an embodiment, the textured region 332 may result in an increase in the emissivity by approximately 5% or more, or by approximately 10% or more compared to the un-textured surface of the susceptor 320.

In FIG. 3A, the textured region 332 is a circular region over a majority of the top surface 331. Though, in other embodiments, the entire top surface 331 may be textured. Alternatively, multiple textured regions 332 may be selectively positioned across the top surface 331, as will be described in greater detail below. Additionally, while portions of the top surface 331 are shown as being textured, it is to be appreciated that the susceptor 320 may be textured on one or more of the top surface 331, the bottom surface, or a sidewall surface.

In an embodiment, the textured region 332 may be textured with any suitable process that can form recessed features into the surface 331 of the susceptor 320. In one embodiment, the texturing process may include a laser patterning process. For example, a laser may be used in order to selectively form holes, trenches, and/or the like into the surface of the susceptor 320.

FIG. 3B is a zoomed in illustration of an area 335 of the textured region 332 in order to more clearly show an example of one textured pattern that may be used to increase the emissivity of the susceptor 320. As shown, the area 335 may comprise an array of holes 336 that are closely packed together. More particularly, the holes 336 are hexagonal holes 336 that are separated by walls 337. The hexagonal holes 336 are packed together in a honeycomb pattern. However, it is to be appreciated that the holes 336 may have any suitable shape (e.g., circular, rectangular, triangular, any polygonal shape, or any irregular shape). Additionally, the holes 336 may be arranged in other layouts, such as in columns or the like. The holes 336 may also be arranged in an irregular pattern in some embodiments. In FIG. 3B the holes 336 all have uniform dimensions. However, it is to be appreciated that the holes 336 may have non-uniform dimensions, such as different widths, different depths, and/or the like. While holes 336 are shown, it is to be appreciated that the textured region 332 may also comprise trenches, lines, and/or any other pattern of recessed surfaces into the surface 331 of the susceptor 320. More generally, the textured region 332 may refer to a surface that has a higher surface roughness than the non-textured portions of the susceptor 320.

Referring now to FIG. 3C, a cross-sectional of the susceptor 320 in the textured region 332 of FIG. 3B along line C-C′ is shown, in accordance with an embodiment. As shown, the textured region 332 may comprise holes 336 that are separated by walls 337. In an embodiment, the use of a laser patterning process enables careful control of the shape and dimensions of the holes 336 and the walls 337. In some embodiments, the holes 336 may have a first width W₁ and the walls 337 may have a second width W₂. The holes 336 may have a depth D. The different dimensions may be in the nanometer range. For example, any of the dimensions W₁, W₂, and/or D may be as small as approximately 100 nm. Embodiments may also include dimensions W₁, W₂, and/or D that are as large as approximately 5 μm. Though, smaller or larger dimensions may also be used in some embodiments.

As shown in FIG. 3C, the pattern of the textured region 332 may be substantially uniform across the surface of the susceptor 320. Though, in other embodiments, the depth D of the various holes 336 may be non-uniform. Similarly, the width W₁ of the holes 336 may be non-uniform and/or the width W₂ of the walls 337 may be non-uniform.

Referring now to FIG. 3D, a cross-sectional illustration of the susceptor 320 in the textured region 332 is shown, in accordance with an embodiment. The susceptor 320 in FIG. 3D may be substantially similar to the susceptor 320 in FIG. 3C, with the exception of the susceptor 320 also including a textured surface on both the top surface and the bottom surface of the susceptor 320. In the illustrated embodiment, the texture on the bottom surface substantially matches the texture on the top surface. For example, the holes 336 and walls 337 are aligned on both the top and bottom surfaces. However, the texture on the bottom surface of the susceptor 320 may be different than the texture on the top surface of the susceptor 320. Additionally, while textured regions on the top surface overlap textured regions on the bottom surface, other embodiments may include a textured region on the top surface that overlies a flat portion of the bottom surface, and/or a textured region on the bottom surface may be provided below a flat portion of the top surface. Additionally, the sidewall surface 338 is shown as being flat, without any texturing. However, it is to be appreciated that the sidewall surface 338 may also be textured in some embodiments. More generally, some embodiments may include a susceptor 320 that has the entirety of all surfaces (i.e., the top surface, the bottom surface, and the sidewall surface 338) textured.

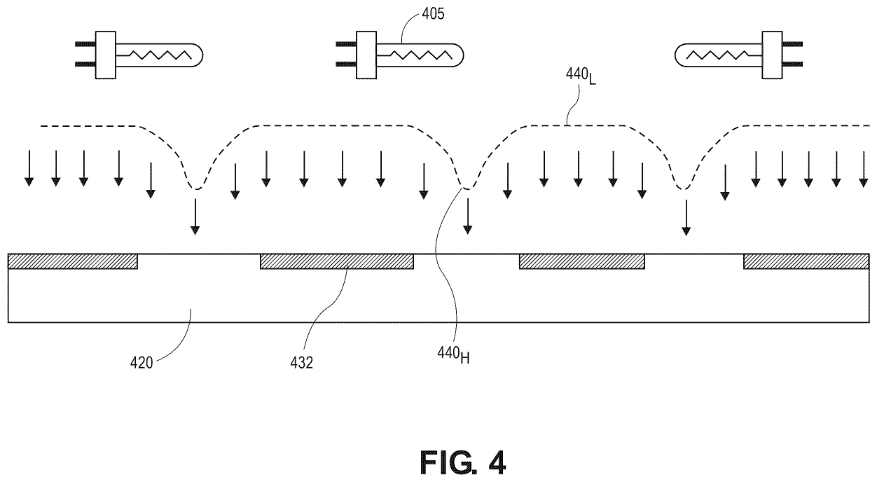

Referring now to FIG. 4, a cross-sectional illustration of a susceptor 420 that is heated by a plurality of lamps 405 is shown, in accordance with an embodiment. In an embodiment, the susceptor 420 may be provided within a tool similar to tool 100 described in greater detail herein. For example, an upper dome (not shown) may be provided between the lamps 405 and the susceptor 420. Additionally, while heating of the top surface of the susceptor 420 is shown as an example, it is to be appreciated that the bottom surface of the susceptor 420 may also be heated by lower lamps (not shown) that emit thermal radiation that passes through a lower dome (not shown).

As shown, the arrangement of the lamps 405 may generally emit a flux 440 of thermal radiation that is directed towards the susceptor 420. In an embodiment, the flux 440 may be non-uniform across a surface of the susceptor 420. The non-uniformity of the flux 440 may be the result of limitations in one or more of the positioning of the lamps 405, design of a reflector (not shown), design of the lamps, and/or the like. For example, current lamp designs may not emit a uniform flux of thermal energy across the entire filament. That is, each individual lamp 405 may inherently provide hot and/or cold spots.

In an embodiment, the flux 440 may have high flux regions 440H and low flux regions 440L. As the total flux 440 is absorbed by the susceptor 420, the susceptor 420 will heat unevenly due to the non-uniform flux 440. For example, the regions of the susceptor 420 that absorb the high flux regions 440H may heat up faster than the regions of the susceptor 420 that absorb the low flux regions 440L. Such a non-uniform heating may be undesirable since the uneven heating can lead to process non-uniformities (e.g., thickness variations in deposited films, etc.).

Accordingly, embodiments described herein may include a susceptor 420 that includes one or more textured regions 432. The textured regions 432 may be aligned with the low flux regions 440L. Pairing textured regions 432 with low flux regions 440L allows for the susceptor 420 to heat more evenly despite the non-uniform flux 440. That is, the higher emissivity of the textured regions 432 may allow for the response to the low flux regions 440L to be similar or the same as the response to the high flux regions 440H. Accordingly, when a profile of the flux 440 is known, the susceptor 420 can be designed to accommodate the inherent flux 440 of the tool in order to provide a more uniform heating of the susceptor 420.

Further, it is to be appreciated that within a given tool, the flux 440 may change over time (e.g., due to degradation of lamps 405, the use of different process recipes, or the like). As the profile of the flux 440 changes different susceptors 420 can be loaded into tool in order to accommodate the different flux 440 profiles. The ability to accommodate different flux 440 profiles through the use of specifically designed susceptors 420 allows for improved flexibility of the tool in order to be used efficiently for different process recipes or the like.

Additionally, it is to be appreciated that direct measurement of the flux 440 may be difficult. Accordingly, some embodiments may use a measure of film thickness uniformity in order to determine the proper placement of the textured regions 432. For example, the portion of the susceptor 420 below a low thickness region of the film may be texturized. Placing the textured regions 432 at locations on the susceptor 420 based on film thickness uniformity measurements may also account for other process condition variables in addition to the flux 440, such as gas flows, chamber architecture, and/or the like.

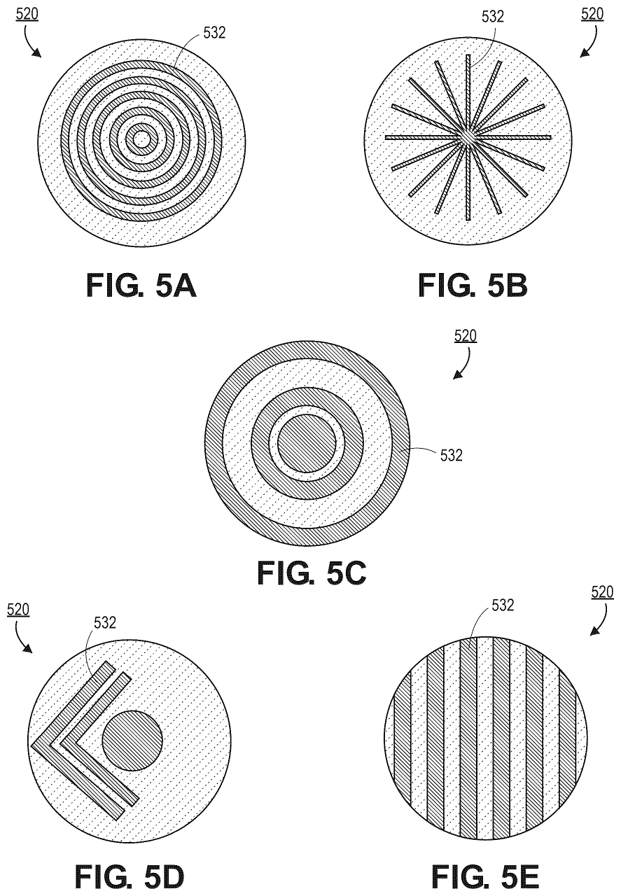

Referring now to FIGS. 5A-5E, a series of plan view illustrations of different susceptors 520 is shown, in accordance with an embodiment. In FIG. 5A the susceptor 520 includes a plurality of textured regions 532. The textured regions 532 may each include a ring, and the plurality of rings may be concentric rings that are evenly spaced. In FIG. 5B, the susceptor 520 may include textured regions 532 in a spoke pattern that extends out from a center of the susceptor 520. In the illustrated embodiments, the spokes stop before an edge of the susceptor 520. Though, in other embodiments, the spokes of the textured regions 532 may extend to an edge of the susceptor 520. In FIG. 5C, the susceptor 520 may include a plurality of textured regions 532 that comprise both rings and a circle. The circle textured region 532 may be provided at a center of the susceptor 520, and the ring shaped textured regions 532 may be concentrically disposed around the circle. In contrast to the rings of FIG. 5A, the ring shaped textured regions 532 in FIG. 5C may have a non-uniform spacing.

In FIG. 5D, the susceptor 520 may have an asymmetric textured region 532 pattern. For example, chevron shaped textured regions 532 may be provided on a first half (i.e., the left half in FIG. 5D) of the susceptor 520 and a second half (i.e., the right half in FIG. 5D) may not have the chevron shaped textured regions 532. Such an embodiment may be useful when the susceptor 520 is positioned with the first half adjacent to the gas input of the chamber, so that the incoming gas is heated faster. The susceptor 520 in FIG. 5D may also include a circular textured region 532 at a center of the susceptor 520.

In FIG. 5E, the susceptor 520 may comprise a plurality of textured regions 532 that are lines across the susceptor 520. For example, a plurality of substantially parallel lines may each traverse the susceptor 520. The lines of the textured regions 532 may extend to the edge of the susceptor 520 (as shown in FIG. 5E). Though, in other embodiments, the lines of one or more of the textured regions 532 may end before reaching the edge of the susceptor 520.

It is to be appreciated that the number, shape, and/or positioning of the textured regions 532 shown in FIGS. 5A-5E are exemplary in nature. That is, embodiments may include one or more textured regions 532 with any desired shape and/or positioning in order to provide the desired heating profile to the susceptor 520. For example, the textured regions 532 may be arranged in order to accommodate cold spots in the tool, similar to the embodiment shown in FIG. 4 described herein. Though, other embodiments may also include a desire to selectively heat different portions of the susceptor at different rates. For example, it may be desirable to heat an outer edge of the susceptor to a temperature above a center of the susceptor for some processing operations. In such an embodiment, the outer circumference of the susceptor 520 may be selectively texturized.

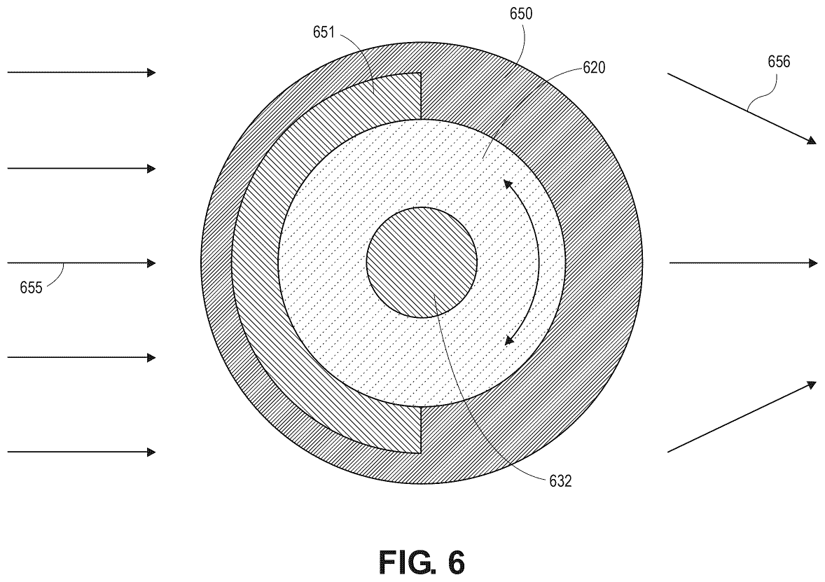

Referring now to FIG. 6, a plan view illustration of a portion of a tool is shown, in accordance with an embodiment. In FIG. 6, the susceptor 620 and a process kit 650 that surrounds the susceptor 620 is shown in isolation for clarity. In an embodiment, gas 655 enters the chamber from the left and passes over the process kit 650 and the susceptor 620 before exiting the chamber (as indicated by lines 656). In an embodiment, the process kit 650 may be a stationary feature within the chamber. The process kit 650 may also include a textured region 651. For example, the textured region 651 is a half ring on a half of the process kit 650 that is adjacent to the input of the gas 655. Accordingly, the process kit 650 with the textured region 651 will heat up faster and provide increased heating of the gas 655 as the gas 655 enters the chamber. This can improve the process outcome in some embodiments.

In FIG. 6, the susceptor 620 may be rotatable, as indicated by the double sided arrow on the perimeter of the susceptor 620. The susceptor 620 may have also have a textured region 632 at a center of the susceptor 620. The textured region 632 may be positioned so that the rotation of the susceptor 620 maintains the symmetry of the textured region 632 with respect to the susceptor 620. Though, it is to be appreciated that the susceptor 620 may comprise one or more textured regions 632 with any suitable patter, such as any of those described in greater detail herein.

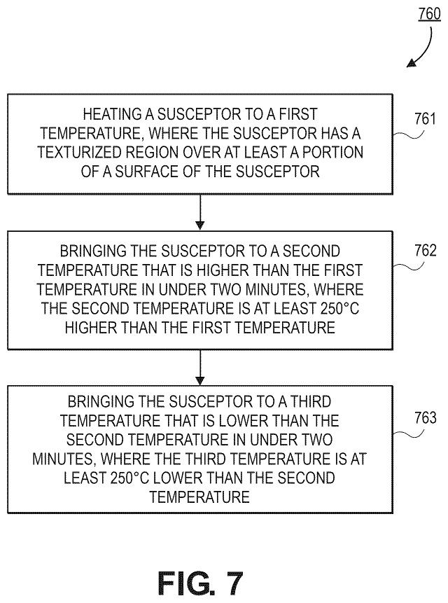

Referring now to FIG. 7, a flow diagram of a process 760 for providing temperature ramps of a susceptor in a tool is shown, in accordance with an embodiment. In an embodiment, the temperature ramps may be used for many different processing recipes. In a particular example, the process 760 may be used as part of a chamber clean within an RTP tool or an epitaxy tool similar to any of the tools described in greater detail herein.

In an embodiment, the process 760 may begin with operation 761, which comprises heating a susceptor to a first temperature. In an embodiment, the susceptor has a texturized region over at least a portion of a surface of the susceptor. The texturized region may be similar to any of the textured surfaces described in greater detail herein. For example, a laser patterning process may be used to form holes, trenches, or the like into a surface of the susceptor. The shape, size, and/or positioning of the textured region may be similar to any of those described in greater detail herein.

In an embodiment, the textured region of the susceptor may be positioned in order to control a heating profile of the susceptor. For example, the textured region may be positioned over “cold” spots inherent to the system in order to provide a more uniform heating of the susceptor. In an embodiment, the first temperature may be approximately 400° C. or more, approximately 600° C. or more, or approximately 650° C. or more.

In an embodiment, the process 760 may continue with operation 762, which comprises bringing the susceptor to a second temperature that is higher than the first temperature in under two minutes. In an embodiment, the second temperature may be at least 250° C. higher than the first temperature. For example, the second temperature may be approximately 650° C. or more, approximately 850° C. or more, or approximately 900° C. or more. The heating may include the emission of thermal radiation from one or more lamps that are directed towards the susceptor. In some embodiments, the temperature ramp may occur in less than one minute.

In an embodiment, the process 760 may continue with operation 763, which comprises brining the susceptor to a third temperature that is lower than the second temperature in under two minutes. In an embodiment, the third temperature may be at least 250° lower than the second temperature. For example, the third temperature may be up to approximately 500° C., up to approximately 600° C., or up to approximately 650° C. In some embodiments, the temperature ramp may occur in less than one minute.

In the embodiments described herein, a susceptor for an RTP or epitaxy tool is described. However, it is to be appreciated that other substrates that are heated may also benefit from textured regions in order to selectively control emissivity of the surface. For example, textured substrates may also include substrate carriers (e.g., wafer carriers) that are used to transfer substrates within a fabrication facility or the like. In such an embodiment, the carrier substrate may be textured across an entire surface (e.g., one or more of a top surface, a bottom surface, or a sidewall surface), or the carrier substrate may be textured selectively, similar to some of the embodiments described in greater detail herein.

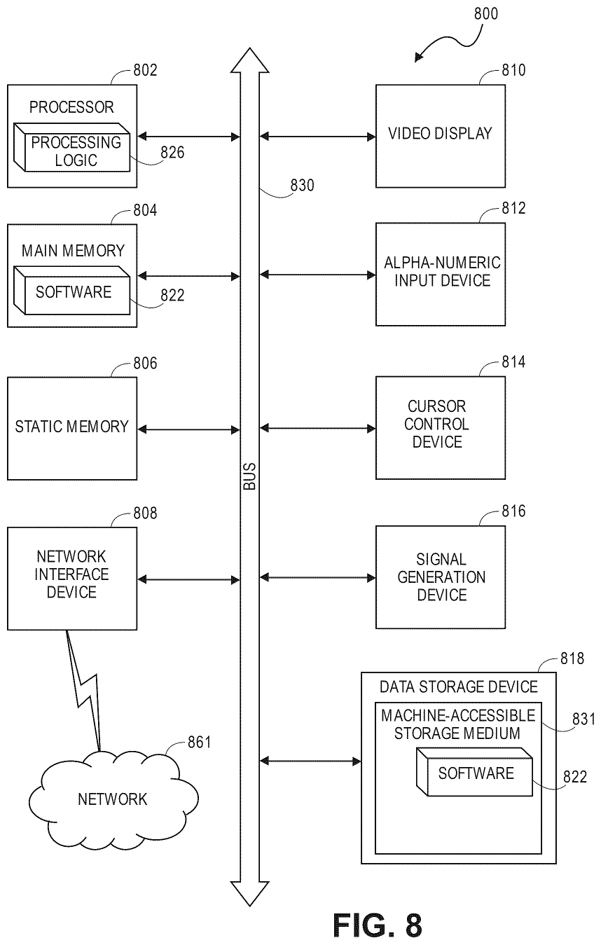

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a substrate with a first emissivity, wherein the substrate comprises a first surface, a second surface, and a sidewall surface that couples the first surface to the second surface; and
a textured region on the first surface, wherein the textured region comprises a second emissivity that is higher than the first emissivity.

2. The apparatus of claim 1, wherein the textured region comprises a plurality of holes into the first surface.

3. The apparatus of claim 2, wherein the plurality of holes comprises hexagon shaped holes in a honeycomb pattern.

4. The apparatus of claim 1, wherein the textured region is a ring on the first surface of the substrate.

5. The apparatus of claim 1, wherein the textured region is a line across at least a portion of the first surface of the substrate.

6. The apparatus of claim 1, wherein the first surface has a first half and a second half, and wherein the textured region is on only the first half.

7. The apparatus of claim 1, wherein a second textured region is on the second surface and/or the sidewall surface.

8. The apparatus of claim 1, wherein the second emissivity is at least 5% higher than the first emissivity.

9. The apparatus of claim 1, wherein the substrate is a susceptor in a rapid thermal processing tool or an epitaxy tool.

10. The apparatus of claim 1, wherein the substrate comprises one or more of silicon, silicon carbide, or graphite.

11. A tool, comprising:
a chamber;
a susceptor in the chamber, wherein the susceptor comprises a surface with a textured region; and
a lamp outside of the chamber, wherein the lamp is configured to emit thermal radiation that passes through the chamber and heats the susceptor.

12. The tool of claim 11, wherein the textured region comprises a plurality of holes into the surface of the susceptor.

13. The tool of claim 12, wherein the plurality of holes have a depth up to 5.0 μm and a width up to 5.0 μm.

14. The tool of claim 12, wherein the plurality of holes are arranged in a honeycomb pattern.

15. The tool of claim 11, wherein the lamp is configured to apply heat to the susceptor with a non-uniform flux across the surface of the susceptor, and wherein the textured region is positioned at a portion of the surface of the susceptor that does not receive a highest flux.

16. The tool of claim 11, further comprising:
a process kit around the susceptor, and wherein a second textured region is provided on the process kit.

17. The tool of claim 16, wherein the chamber comprises a gas inlet at a side of the chamber, and wherein the second textured region is on the process kit adjacent to the gas inlet.

18. A method, comprising:
heating a susceptor to a first temperature, wherein the susceptor has a textured region over at least a portion of a surface of the susceptor;
bringing the susceptor to a second temperature that is higher than the first temperature in under two minutes, wherein the second temperature is at least 250° C. higher than the first temperature; and
bringing the susceptor to a third temperature that is lower than the second temperature in under two minutes, wherein the third temperature is at least 250° C. lower than the second temperature.

19. The method of claim 18, wherein the textured region comprises a plurality of hexagonal holes in a honeycomb pattern.

20. The method of claim 18, wherein the first temperature is at least 400° C. and the second temperature is at least 650° C.
